(19) United States
(12) Patent Application Publication
(10) Pub. No.: US 2018/0269221 A1
(43) Pub. Date: Sep. 20, 2018

(54) SEMICONDUCTOR DEVICE

(71) Applicant: Toshiba Memory Corporation, Minato-ku (JP)

(72) Inventors: Tatsuhiro ODA, Yokohama (JP); Sachiyo Ito, Kawasaki (JP)

(73) Assignee: Toshiba Memory Corporation, Minato-ku (JP)

(21) Appl. No.: 15/788,855

(22) Filed: Oct. 20, 2017

(30) Foreign Application Priority Data
Mar. 17, 2017 (JP) 2017-053335

(51) Int. Cl. H01L 27/11575; H01L 27/11565; H01L 27/11582

(52) U.S. Cl. CPC H01L 27/11575; H01L 27/11582; H01L 27/11565

(57) ABSTRACT

According to an embodiment, a semiconductor device includes a substrate, a stacked body, and a second insulating film. A first insulating film and an electrode film are alternately stacked in the stacked body so as to extend in a first direction along an upper surface of the substrate. The stacked body includes an end portion in the first direction, a shape of the end portion being a staircase shape. The second insulating film is provided in first and second regions, the end portion being provided in the first region, the second region being contiguous to the first region in the first direction. The second insulating film includes a part in which a width of a second direction in the second region is smaller than a width of the second direction in the first region, the second direction crossing the first direction and along the upper surface of the substrate.

### CROSS-REFERENCE TO RELATED APPLICATIONS

This application is based upon and claims the benefit of priority from Japanese Patent Application No. 2017-053335, filed on Mar. 17, 2017; the entire contents of which are incorporated herein by reference.

### FIELD

Embodiments relate generally to a semiconductor device.

### BACKGROUND

A semiconductor memory device having a three-dimensional structure has a structure in which a memory cell array including a plurality of memory cells and a peripheral circuit are integrated. In the memory cell array, a stacked body obtained by stacking a plurality of electrode films is provided, and in the stacked body, a memory hole is formed. An end portion of the stacked body is processed into a staircase shape, and each electrode film is drawn out to the outside of the stacked body through an insulating film. There is a problem that the stacked body is deformed in such a staircase-shaped end portion due to the occurrence of internal stress by the insulating film.

### BRIEF DESCRIPTION OF THE DRAWINGS

FIG. 1 is a plan view showing a semiconductor device according to a first embodiment;

FIG. 2 is a sectional view taken along a line A1-A2 of FIG. 1;

FIG. 3 is a plan view showing a part of the semiconductor device according to the first embodiment;

FIG. 4 is a sectional view taken along a line B1-B2 of FIG. 3;

FIG. 5 is a view for illustrating the occurrence of internal stress in a semiconductor device;

FIG. 6 is a plan view showing a part of a semiconductor device according to a second embodiment; and

FIG. 7 is a sectional view taken along a line C1-C2 of FIG. 6.

### DETAILED DESCRIPTION

According to an embodiment, a semiconductor device includes a substrate, a stacked body, and a second insulating film. The stacked body is provided on the substrate. A first insulating film and an electrode film are alternately stacked in the stacked body so as to extend in a first direction along an upper surface of the substrate. The stacked body includes an end portion in the first direction, a shape of the end portion being a staircase shape. The second insulating film is provided in a first region and a second region, the end portion being provided in the first region, the second region being contiguous to the first region in the first direction. The second insulating film includes a part in which a width of a second direction in the second region is smaller than a width of the second direction in the first region, the second direction crossing the first direction and along the upper surface of the substrate.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

As one example, a case where the semiconductor device is a semiconductor memory device having a three-dimensional structure will be described.

### First Embodiment

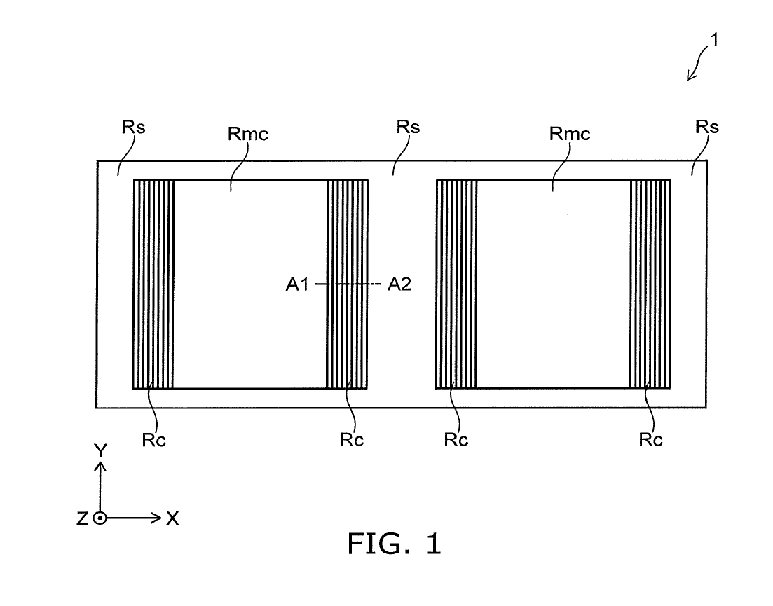

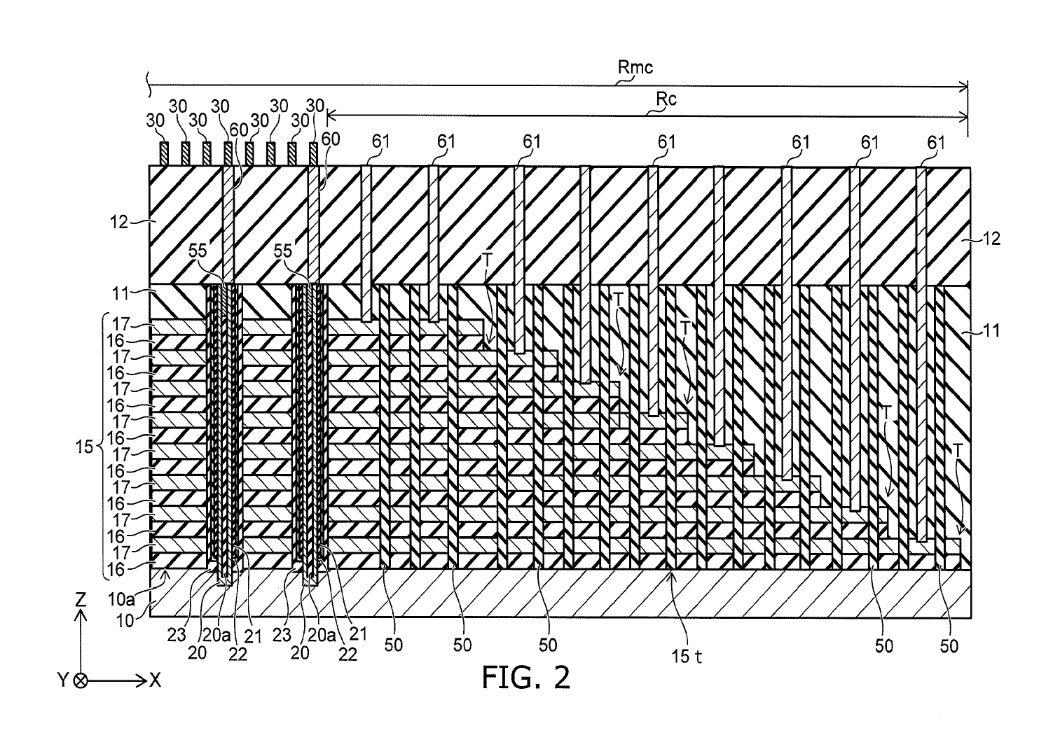

FIG. 1 is a plan view showing a semiconductor device 1. FIG. 2 is a sectional view taken along a line A1-A2 of FIG. 1.

As shown in FIG. 1 and FIG. 2, in the semiconductor device 1, a substrate 10 containing silicon (Si) or the like is provided. Hereinafter, in the specification, for the sake of convenience of description, an XYZ orthogonal coordinate system is adopted. Two directions parallel to an upper surface 10a of the substrate 10 and also orthogonal to each other are referred to as “X-direction” and “Y-direction”, and a direction perpendicular to the upper surface 10a is referred to as “Z-direction”.

As shown in FIG. 1, in the semiconductor device 1, a cell region Rmc and a peripheral region Rs are provided.

In the cell region Rmc, a memory cell array including a plurality of memory cells is provided. The shape of the cell region Rmc when viewed from the Z-direction is, for example, a rectangle. The cell region Rmc includes a contact region Rc. For example, the contact region Rc is located on both ends in the cell region Rmc. The peripheral region Rs is located in the periphery of the cell region Rmc. In the peripheral region Rs, a peripheral circuit (not shown) such as a row decoder or a sense amplifier is provided.

In the example shown in FIG. 1, two cell regions Rmc are spaced from each other and arranged along the X-direction. The contact region Rc is located on both ends in the X-direction in each cell region Rmc. The peripheral region Rs is located in the periphery of each cell region Rmc. Incidentally, the number of cell regions Rmc and peripheral regions Rs is arbitrary, and the number of contact regions Rc formed in the cell region Rmc is arbitrary. For example, the contact region Rc may be formed in one end in the X-direction in the cell region Rmc, or may be formed in both ends in the X-direction and in both ends in the Y-direction.

As shown in FIG. 2, in the cell region Rmc, a stacked body 15 and a silicon pillar 20 (semiconductor pillar) are provided. In the stacked body 15, a plurality of insulating films 16 and a plurality of electrode films 17 are provided, and the insulating film 16 and the electrode film 17 are alternately stacked in the Z-direction one by one. The number of stacked insulating films 16 and electrode films 17 is arbitrary. The insulating film 16 contains, for example, silicon oxide (SiO). The electrode film 17 contains, for example, tungsten (W). Further, on the stacked body 15, an insulating film 11 containing silicon oxide or the like is provided.

Among the plurality of electrode films 17, the electrode film 17 located in the lowermost layer is a source-side select gate, and is provided on the substrate 10 through the insulating film 16. Among the plurality of electrode films 17, the electrode film 17 located in the uppermost layer is a drain-side select gate. Among the plurality of electrode films 17, the electrode films 17 provided between the lowermost layer of the electrode film 17 (source-side select gate) and the uppermost layer of the electrode film 17 (drain-side select gate) are word lines.

The silicon pillar 20 extends in the Z-direction. The silicon pillar 20 pierces the insulating film 11 and the stacked body 15, and a lower end thereof is in contact with the substrate 10. The silicon pillar 20 contains, for example, silicon. The shape of the silicon pillar 20 is, for example, a circular columnar shape.

The silicon pillar 20 has an insulating core portion 20a. The insulating core portion 20a contains, for example, silicon oxide. Incidentally, the silicon pillar 20 may not be provided with the insulating core portion 20a.

On the insulating core portion 20a, a plug portion 55 containing silicon or the like is provided. The periphery, that is, the side surface of the plug portion 55 is surrounded by the silicon pillar 20.

In the periphery of the silicon pillar 20, a tunnel insulating film 21 is provided. The tunnel insulating film 21 contains, for example, silicon oxide.

In the periphery of the tunnel insulating film 21, a charge storage film 22 is provided. The charge storage film 22 is a film for storing electric charge, and contains, for example, silicon nitride (SiN).

In the periphery of the charge storage film 22, a block insulating film 23 is provided. The block insulating film 23 contains, for example, silicon oxide.

In a region immediately above the silicon pillar 20, a contact 60 is provided. On the insulating film 11, an insulating film 12 containing silicon oxide or the like is provided. The contact 60 extends in the Z-direction in the insulating film 12. The contact 60 contains, for example, a conductive material such as tungsten.

On the insulating film 12, a plurality of bit lines 30 is provided. The bit line 30 extends in the Y-direction, and is connected to the silicon pillar 20 through the contact 60 and the plug portion 55.

In the contact region Rc, an end portion 15t of the stacked body 15 is provided. The shape of the end portion 15t of the stacked body 15 is a staircase shape such that a terrace T is formed in the electrode film 17. Here, a staircase-shaped structure refers to a structure in which terraces on horizontal and vertical planes in a staircase shape are alternately arranged. The insulating film 11 covers the end portion 15t in a staircase shape.

The terrace T of the end portion 15t is provided with a plurality of support bodies 50. The support body 50 pierces the insulating film 11 and the stacked body 15 to reach the substrate 10. A lower end of the support body 50 is in contact with an upper surface 10a of the substrate 10. The support body 50 contains, for example, silicon oxide. The shape of the support body 50 is, for example, a circular columnar shape or a polygonal columnar shape. Incidentally, the number of support bodies 50 and the position of the support body 50 with respect to the terrace T are arbitrary.

On the terrace T of the end portion 15t, a contact 61 is provided. The contact 61 extends in the Z-direction in the insulating film 11 and the insulating film 12. A lower end of the contact 61 is connected to the electrode film 17. The contact 61 contains, for example, a conductive material such as tungsten. The shape of the contact 61 is, for example, a circular columnar shape or a polygonal columnar shape. Incidentally, the number of contacts 61 and the position of the contact 61 with respect to the terrace T are arbitrary.

On the insulating film 12, an upper layer interconnect (not shown) extending in the X-direction is provided. An upper end of the contact 61 is connected to an upper layer interconnect. That is, the electrode film 17 is connected to the upper layer interconnect through the contact 61.

In the cell region Rmc, a lot of memory cells are arranged in a three-dimensional matrix along the X-direction, Y-direction, and Z-direction, and data can be stored in each memory cell. Further, in the contact region Rc, each electrode film 17 is drawn out and is connected to a peripheral circuit through the contact 61 and the upper layer interconnect.

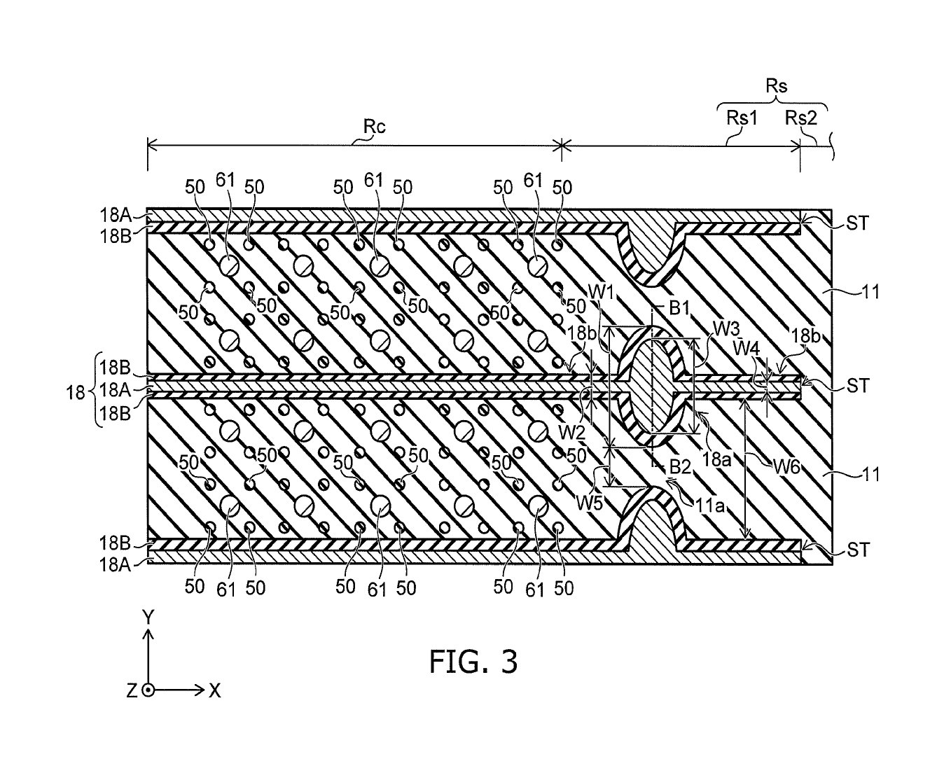

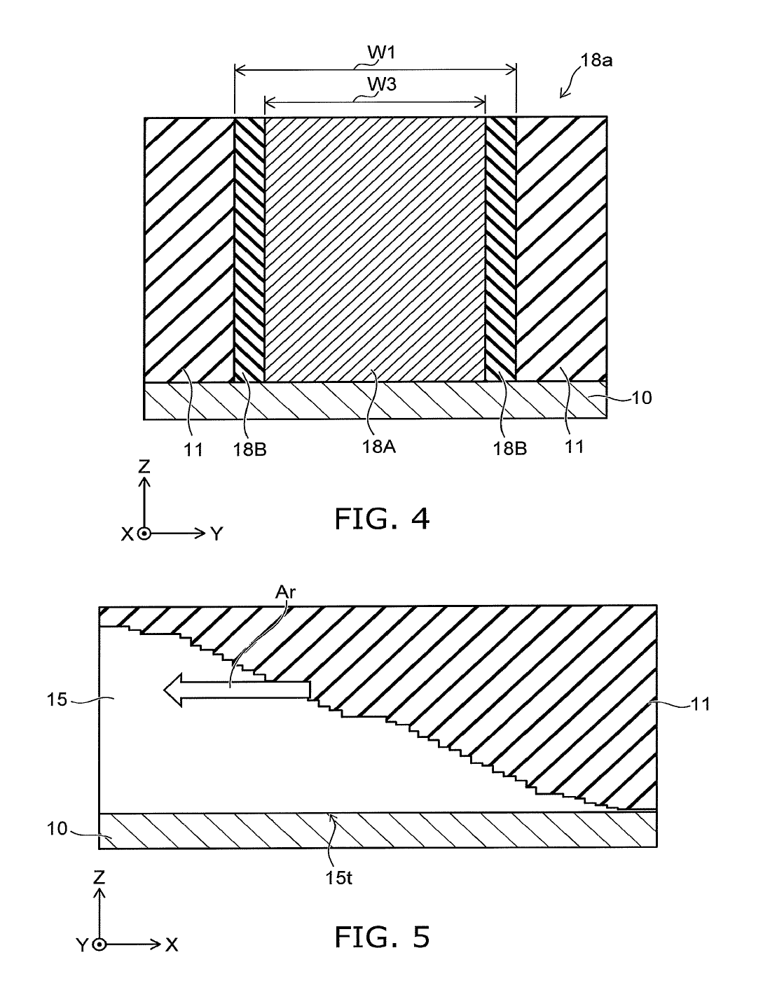

FIG. 3 is a plan view showing a part of the semiconductor device 1. FIG. 4 is a sectional view taken along a line B1-B2 of FIG. 3. In FIG. 3, a vicinity of a boundary between the contact region Rc of the cell region Rmc and the peripheral region Rs is shown in an enlarged view. FIG. 4 is a Y-Z sectional view of a wide part 18a of a device isolation portion 18.

As shown in FIG. 3, a plurality of slits ST is formed in the semiconductor device 1. The slit ST extends in the Z-direction in the stacked body 15 and the insulating film 11.

Further, the slit ST extends in the X-direction from the cell region Rmc to a part of the peripheral region Rs. In the peripheral region Rs, when a region in which the slit ST is formed is defined as a region Rs1, for example, a peripheral circuit is provided in a region Rs2 contiguous to the region Rs1 in the X-direction. That is, in the X-direction, the region Rs1 of the peripheral region Rs is located between the contact region Rc of the cell region Rmc and the region Rs2 of the peripheral region Rs.

The slit ST divides the stacked body 15 into a plurality of regions in the Y-direction. The regions divided by the slit ST are called “blocks”. In each block, the silicon pillar 20 in the cell region Rmc and the support body 50 and the contact 61 in the contact region Rc are located. The silicon pillar 20 selected one by one from each block is electrically connected to one bit line 30. Further, in the example shown in FIG. 3, in each block, four support bodies 50 are located around the contact 61, and a plurality of such arrangements is formed.

In the slit ST, the device isolation portion 18 is provided. The device isolation portion 18 extends along the Z-direction and X-direction. The device isolation portion 18 has an interconnect portion 18A and a side wall 18B. The interconnect portion 18A extends along the Z-direction and X-direction. A lower end of the interconnect portion 18A is in contact with the substrate 10. An upper end of the interconnect portion 18A is connected to a source line (not shown) extending in the Y-direction through a contact. That is, the interconnect portion 18A constitutes a part of the source line. The interconnect portion 18A contains a conductive material, and for example, contains a metal such as tungsten or titanium or silicon.

The side wall 18B is provided on a side surface of the interconnect portion 18A. The side wall 18B is located between a structure body of the stacked body 15 and the insulating film 11 and the interconnect portion 18A in the cell region Rmc, and is located between the insulating film 11 and the interconnect portion 18A in the peripheral region Rs. The side wall 18B has an insulating property and electrically insulates the electrode film 17 of the stacked body 15 and the interconnect portion 18A from each other in the cell region Rmc. The side wall 18B contains, for example, silicon oxide.

As shown in FIG. 3 and FIG. 4, the device isolation portion 18 is provided with the wide part 18a and a plate-shaped part 18b. The wide part 18a is a part whose width expands in the Y-direction as compared with the plate-shaped part 18b. That is, in the slit ST, a part whose width expands in the Y-direction as compared with the other part is formed.

The wide part 18a is located, for example, between the plate-shaped parts 18b. The shape of the wide part 18a is a columnar shape whose width expands in both sides in the Y-direction, and is, for example, a circular column or an elliptic column. The shape of the wide part 18a may be a prismatic column such as a quadrangular column.

A width W1 of the wide part 18a is larger than a width W2 of the plate-shaped part 18b. In the example shown in FIG. 3 and FIG. 4, the width W1 and the width W2 are widths in the Y-direction of the wide part 18a and the plate-shaped part 18b, respectively. The width of the wide part 18a expands on both sides in the Y-direction, but may expand on one side in the Y-direction.

In the wide part 18a, the shape of the interconnect portion 18A is a columnar shape whose width expands on both sides in the Y-direction, and is, for example, a circular column or an elliptic column. The shape of the interconnect portion 18A may be a prismatic column such as a quadrangular column. In the wide part 18a, an insulator such as a silicon oxide film may be buried in the interconnect portion 18A.

In the plate-shaped part 18b, the shape of the interconnect portion 18A is, for example, a plate shape.

A width W3 of the interconnect portion 18A of the wide part 18a is larger than a width W4 of the interconnect portion 18A of the plate-shaped part 18b.

Incidentally, in the wide part 18a, the side wall 18B may be provided such that the width expands on both sides in the Y-direction. In this case, the width of the side wall 18B of the wide part 18a becomes larger as compared with the plate-shaped part 18b.

There is a difference in the width of the insulating film 11 provided between the device isolation portions 18 adjacent to each other in the Y-direction between the wide part 18a and the plate-shaped part 18b. A width W5 of the insulating film 11 between the wide parts 18a is smaller than a width W6 of the insulating film 11 between the plate-shaped parts 18b. That is, the insulating film 11 has a narrow part 11a whose width narrows between the wide parts 18a. Since the narrow part 11a is provided, the insulating film 11 extending in the X-direction is not completely divided by the wide part 18a.

Hereinafter, effects of the embodiment will be described.

FIG. 5 is a view for illustrating the occurrence of internal stress in a semiconductor device.

In a semiconductor device having a three-dimensional structure, in a staircase-shaped end portion of a stacked body, each electrode film is drawn out to the outside of the stacked body through an insulating film. There is a fear that the stacked body is deformed in such a staircase-shaped end portion due to the occurrence of internal stress by the insulating film.

As shown in FIG. 5, by the insulating film 11 covering the end portion 15t of the stacked body 15, internal stress (for example, compressive stress) occurs in the direction of the arrow Ar (−X-direction) in the stacked body 15. For example, when the electrode film 17 is formed, after a silicon oxide film and a silicon nitride film are alternately stacked on the substrate 10, the silicon nitride film is removed through the slit, and a metal film containing tungsten or the like is buried in a space formed by removing the silicon nitride film. In the process of selectively removing such a silicon nitride film, the inside of the stacked body 15 is in a state where the silicon oxide films are formed through the space, and therefore, due to the internal stress by the insulating film 11 covering the end portion 15t of the stacked body 15, the stacked body 15 is likely to be deformed in the direction of the arrow Ar. Further, in the staircase-shaped end portion 15t of the stacked body 15, there is a fear that the support body 50 located around the contact 61 may be bent and the support body 50 and the contact 61 come into contact with each other.

On the other hand, as a method for relaxing the internal stress of the stacked body 15 by the insulating film 11, there is a method in which the slits ST adjacent to each other in the Y-direction are connected in the peripheral region Rs to divide the insulating film 11 extending in the X-direction. However, in this method, the internal stress by the insulating film 11 can be relaxed, but internal stress by the insulating film 16 stacked in the stacked body 15 occurs in a direction (X-direction) opposite to the direction of the arrow Ar, and as a result of relaxation of the internal stress by the insulating film 11, the stacked body 15 is deformed in the direction opposite to the direction of the arrow Ar due to the internal stress by the insulating film 16 in some cases.

In the semiconductor device 1 of the embodiment, the device isolation portion 18 has the wide part 18a in the region Rs1 of the peripheral region Rs located outside the contact region Rc of the cell region Rmc. By providing such a wide part 18a, the width in the Y-direction of the insulating film 11 (narrow part 11a) in the vicinity of the wide part 18a can be made narrow. By doing this, in the region Rs1 of the peripheral region Rs, a part of the insulating film 11 extending in the X-direction can be divided. The division of the part of the insulating film 11 in this manner relaxes the internal stress by the insulating film 11 so that the deformation (deformation in the −X-direction) of the stacked body 15 is suppressed, and also the deformation (deformation in the X-direction) of the stacked body 15 due to the internal stress by the insulating film 16 is suppressed. Accordingly, the deformation of the stacked body 15 is suppressed so that the displacement of the contact 61 due to the deformation of the stacked body 15 is suppressed.

According to the embodiment, a semiconductor device having high reliability is provided.

### Second Embodiment

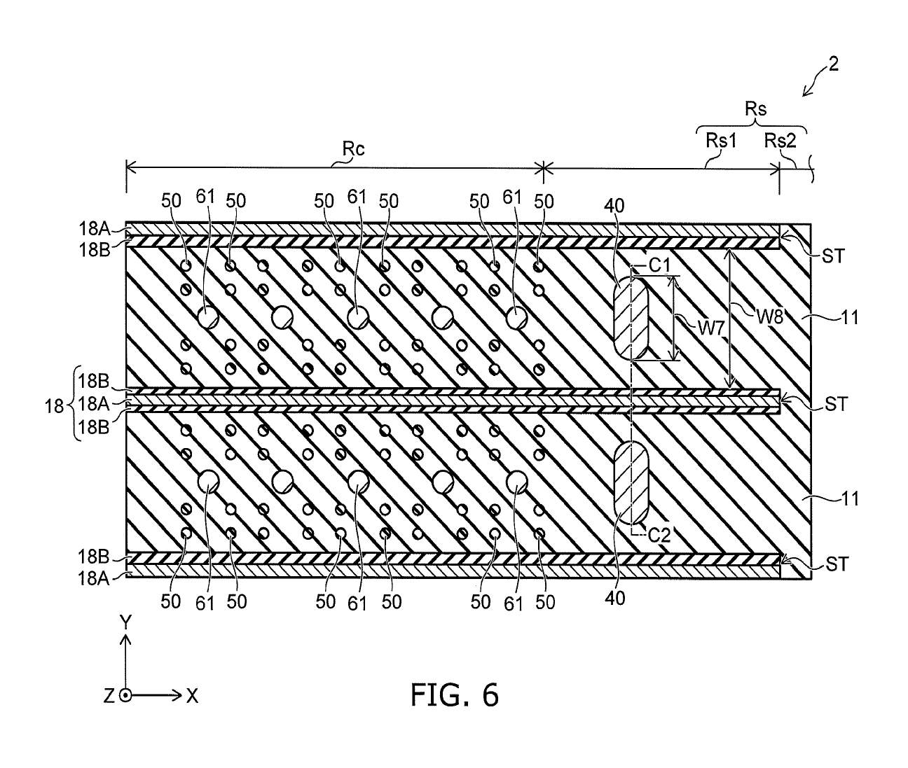

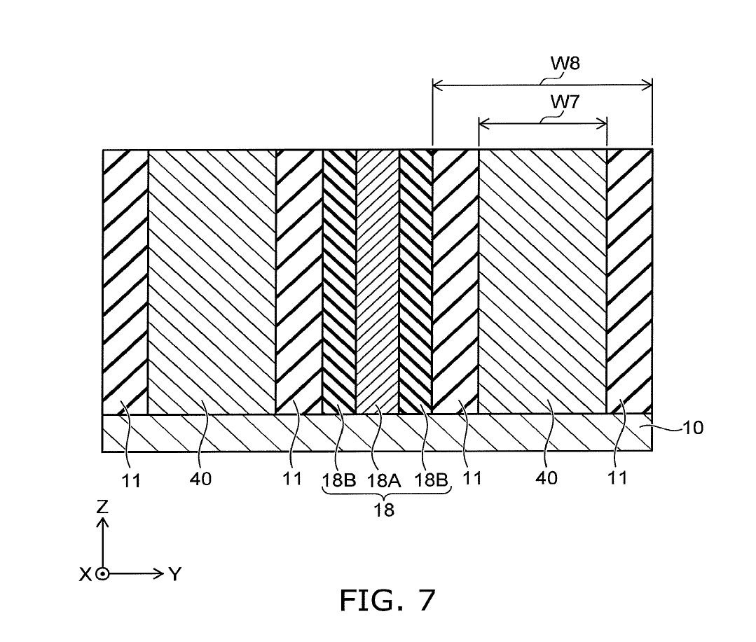

FIG. 6 is a plan view showing a part of a semiconductor device 2. FIG. 7 is a sectional view taken along a line C1-C2 of FIG. 6.

A region shown in FIG. 6 corresponds to the region shown in FIG. 3, and in FIG. 6, a vicinity of a boundary between a contact region Rc of a cell region Rmc and a peripheral region Rs is shown in an enlarged view.

In the embodiment, the embodiment and the first embodiment are different in the structure of the device isolation portion 18 and the conductive portion 40. The other configuration is the same as that of the first embodiment, and therefore, a detailed description of the other configuration will be omitted.

As shown in FIG. 6 and FIG. 7, a plurality of slits ST is formed in the semiconductor device 1. The slit ST extends in the X-direction from the cell region Rmc to a region Rs1 of the peripheral region Rs.

In the slit ST, a device isolation portion 18 is provided. The shape of the device isolation portion 18 is, for example, a plate shape. The device isolation portion 18 has an interconnect portion 18A and a side wall 18B.

In a region Rs1 of the peripheral region Rs, a conductive portion 40 is provided. The conductive portion 40 is located between the device isolation portions 18 adjacent to each other in the Y-direction. A lower end of the conductive portion 40 is located on a substrate 10. On an upper end of the conductive portion 40, an insulating film (for example, an insulating film 12) is provided. The conductive portion 40 contains, for example, a metal such as tungsten or titanium or silicon.

The shape of the conductive portion 40 is, for example, a circular column or an elliptic column. The shape of the conductive portion 40 may be a prismatic column such as a quadrangular column. A width W7 in the Y-direction of the conductive portion 40 is smaller than a width W8 in the Y-direction of the insulating film 11 provided between the device isolation portions 18. According to this, the insulating film 11 extending in the X-direction is not completely divided by the conductive portion 40.

Hereinafter, effects of the embodiment will be described.

In the semiconductor device 2 of the embodiment, the conductive portion 40 is provided in the region Rs1 of the peripheral region Rs located outside the contact region Rc of the cell region Rmc and between the device isolation portions 18. By providing such a conductive portion 40, a part of the insulating film 11 in the vicinity of the conductive portion 40 can be divided. According to this, the internal stress by the insulating film 11 is relaxed so that the deformation (deformation in the −X-direction) of the stacked body 15 is suppressed, and also the deformation (deformation in the X-direction) of the stacked body 15 due to the internal stress by the insulating film 16 is suppressed. Accordingly, the deformation of the stacked body 15 is suppressed so that the displacement of the contact 61 due to the deformation of the stacked body 15 is suppressed.

According to the embodiment, a semiconductor device having high reliability is provided.

As described above, as one example, a case where the semiconductor device according to the respective embodiments is a semiconductor memory device having a three-dimensional structure is described, however, the semiconductor device according to the respective embodiments is not limited to the semiconductor memory device having a three-dimensional structure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate;
a stacked body provided on the substrate, a first insulating film and an electrode film being alternately stacked in the stacked body so as to extend in a first direction along an upper surface of the substrate, the stacked body including an end portion in the first direction, a shape of the end portion being a staircase shape; and
a second insulating film provided in a first region and a second region, the end portion being provided in the first region, the second region being contiguous to the first region in the first direction,
the second insulating film including a part in which a width of a second direction in the second region is smaller than a width of the second direction in the first region, the second direction crossing the first direction and along the upper surface of the substrate.

2. The device according to claim 1, further comprising
a device isolation portion, a part of the device isolation portion being provided in the stacked body,
wherein the device isolation portion extends in the first direction in the first region and the second region, and
the device isolation portion includes a wide part whose width expands in the second region.

3. The device according to claim 2, wherein a width of the wide part expands in the second direction.

4. The device according to claim 2, wherein a shape of the wide part is any of a circular column, an elliptic column, and a prismatic column.

5. The device according to claim 2, wherein
the device isolation portion includes an interconnect portion extending in the first direction and a side wall provided on a side surface of the interconnect portion, and
a width of one of the interconnect portion and the side wall expands in the wide part.

6. The device according to claim 5, wherein the width of the interconnect portion expands in the second direction in the wide part.

7. The device according to claim 6, wherein a shape of the interconnect portion is any of a circular column, an elliptic column, and a prismatic column.

8. The device according to claim 2, wherein
the device isolation portion further includes plate-shaped parts, the wide part being located between the plate-shaped parts in the first direction, and
a width in the second direction of the wide part is larger than a width in the second direction of the plate-shaped part.

9. The device according to claim 1, further comprising
a semiconductor pillar provided in the stacked body and extending in a stacking direction of the stacked body, and
wherein the first region is located between a third region and the second region in the first direction, the semiconductor pillar being provided in the third region.

10. The device according to claim 9, further comprising a charge storage film provided between the stacked body and the semiconductor pillar.

11. The device according to claim 1, further comprising:
a contact provided on the end portion of the stacked body, and on a terrace formed for each of the electrode films, and
a plurality of support bodies provided in the end portion of the stacked body, extending in a stacking direction of the stacked body, and located around the contact.

12. The device according to claim 1, wherein the second insulating film contains silicon oxide.

13. A semiconductor device comprising:
a substrate;
a stacked body provided on the substrate, a first insulating film and an electrode film being alternately stacked in the stacked body so as to extend in a first direction along an upper surface of the substrate, the stacked body including an end portion in the first direction, a shape of the end portion being a staircase shape; and
a second insulating film provided in a first region and a second region, the end portion being provided in the first region, the second region being contiguous to the first region in the first direction,
a plurality of device isolation portions provided in the stacked body, and extending in the first direction in each of the first region and the second region, and
a conductive portion provided in the second insulating film,
the conductive portion being located between the device isolation portions in the second region, and dividing a part of the second insulating film.

14. The device according to claim 13, wherein a shape of the conductive portion is any of a circular column, an elliptic column, and a prismatic column.

15. The device according to claim 13, wherein the conductive portion contains any of tungsten, titanium, and silicon.

16. The device according to claim 13, wherein
the device isolation portion includes an interconnect portion extending in the first direction and a side wall provided on a side surface of the interconnect portion.

17. The device according to claim 13, further comprising
a semiconductor pillar provided in the stacked body and extending in a stacking direction of the stacked body,
wherein the first region is located between a third region and the second region in the first direction, the semiconductor pillar being provided in the third region.

18. The device according to claim 17, further comprising a charge storage film provided between the stacked body and the semiconductor pillar.

19. The device according to claim 13, further comprising:
a contact provided on the end portion of the stacked body, and on a terrace formed for each of the electrode films, and
a plurality of support bodies provided in the end portion of the stacked body, extending in a stacking direction of the stacked body, and located around the contact.

20. The device according to claim 13, wherein the second insulating film contains silicon oxide.
